(19) United States
(12) Patent Application Publication
(10) Pub. No.: US 2025/0153964 A1
(43) Pub. Date: May 15, 2025

(54) TAPE FEEDER AND METHOD FOR FEEDING COVER TAPE

(71) Applicant: FUJI CORPORATION, Chiryu (JP)

(72) Inventor: Norio HOSOI, Chiryu-shi (JP)

(73) Assignee: FUJI CORPORATION, Chiryu (JP)

(21) Appl. No.: 18/728,524

(22) PCT Filed: Feb. 15, 2022
(86) PCT No.: PCT/JP2022/005865

§ 371 Date: Jul. 12, 2024

(51) Int. Cl. B65H 18/10; B65H 23/18; H05K 13/04

(52) U.S. Cl. CPC B65H 18/103; B65H 23/1806; H05K 13/0419; B65H 2403/40; B65H 2403/72; B65H 2403/732; B65H 2701/37

(57) ABSTRACT

A tape feeder of feeds a component supply tape to a predetermined supply position and peels off a cover tape from the carrier tape at the supply position to expose a component. The tape feeder includes a pair of feed gears configured to mesh with each other and sandwich the cover tape, a drive motor configured to rotationally drive the pair of feed gears such that the carrier tape is pulled in, a rotation gear directly or indirectly meshed with a first feed gear of the feed gears, a one-way clutch provided in the rotation gear such that the rotation gear idles with respect to rotation of the pair of feed gears in a direction in which the carrier tape is pulled in, and a torque limiter provided in the rotation gear or another rotation gear meshing with the rotation gear.

### TECHNICAL FIELD

The present description discloses a tape feeder and a method for feeding a cover tape.

### BACKGROUND ART

Conventionally, there is known a tape feeder that supplies a component by conveying a carrier tape to a supply position while peeling off a cover tape from a component supply tape in which the cover tape is attached to the carrier tape storing components to be mounted on a board. For example, Patent Literature 1 discloses a tape feeder in which a cover tape is peeled off by sandwiching and pulling in the cover tape between a pair of pull-in gears that mesh with each other. In this tape feeder, in order to prevent return of the cover tape, a one-way clutch is fitted between a first pull-in gear of the pair of pull-in gears and a rotation shaft thereof. Further, in this tape feeder, in order to return the cover tape, for example, in a case where an operator erroneously pulls out the cover tape in excess, a friction force of a fitting section between the pull-in gear and the one-way clutch is adjusted such that the pull-in gear performs slip rotation in the opposite direction with respect to the one-way clutch when a large force acts on the first pull-in gear in a direction opposite to a peeling direction of the cover tape.

### Patent Literature

Patent Literature 1: JP-A-2017-191891

### BRIEF SUMMARY

### Technical Problem

However, in the tape feeder described in Patent Literature 1, since the one-way clutch is disposed between the pull-in gear and the rotation shaft, the pull-in gear becomes large. Since other members such as a motor are disposed around the pull-in gear, when the pull-in gear becomes large, the arrangement space of other members such as a motor is locally tight, and the entire tape feeder becomes large.

A main object of the present disclosure is to effectively utilize a limited space and suppress an increase in size of the entire feeder even when a one-way clutch or a torque limiter is disposed.

### Solution to Problem

According to an aspect of the present disclosure, there is provided a tape feeder for feeding a component supply tape, in which a cover tape is attached to a carrier tape accommodating multiple components, to a predetermined supply position and peeling off the cover tape from the carrier tape in front of the supply position to expose the component on the carrier tape, the tape feeder including:
a pair of feed gears configured to mesh with each other and sandwich the cover tape;
a drive motor configured to rotationally drive the pair of feed gears such that the carrier tape is pulled in;
a rotation gear directly or indirectly meshed with a first feed gear of the pair of feed gears;
a one-way clutch provided in the rotation gear such that the rotation gear idles with respect to rotation of the pair of feed gears in a direction in which the carrier tape is pulled in; and
a torque limiter provided in the rotation gear or another rotation gear meshing with the rotation gear.

In this tape feeder, an increase in size of the entire feeder can be suppressed.

According to an aspect of the present disclosure, there is provided a method for feeding a cover tape by using a pair of feed gears capable of rotating in opposite directions to each other in a state in which a carrier tape accommodating multiple components is sandwiched in a component supply tape in which the cover tape is attached to the carrier tape, the method including:
causing a rotation gear to directly or indirectly mesh with a first feed gear of the pair of feed gears;
causing the rotation gear to idle with respect to rotation of the first feed gear in a direction in which the cover tape is pulled in to peel off the cover tape; and
causing the rotation gear to slip with respect to rotation of the first feed gear in a direction in which the cover tape is fed to a side opposite to a peeling direction of the cover tape.

Also in this cover tape feeding method, the same effect as that of the tape feeder of the present disclosure is achieved.

### BRIEF DESCRIPTION OF DRAWINGS

FIG. 1 is a schematic configuration view of component mounting system 1.

FIG. 2 is a perspective view of feeder table 20 and tape feeder 30.

FIG. 3 is a perspective view of tape reel 60.

FIG. 4 is a side view of main body portion 50.

FIG. 5 is a side view of cover tape pull-in mechanism 80.

FIG. 6 is a cross-sectional view of rotation gear 86 taken along a plane orthogonal to fixed shaft 87.

FIG. 7 is a cross-sectional view of rotation gear 86 taken along a plane passing through fixed shaft 87.

FIG. 8A is a view illustrating a state of rotation of various gears.

FIG. 8B is a view illustrating the state of rotation of various gears.

FIG. 9 is a cross-sectional view of rotation gear 86 according to a modification taken along a plane passing through fixed shaft 87 and rotation shaft 187.

### DESCRIPTION OF EMBODIMENTS

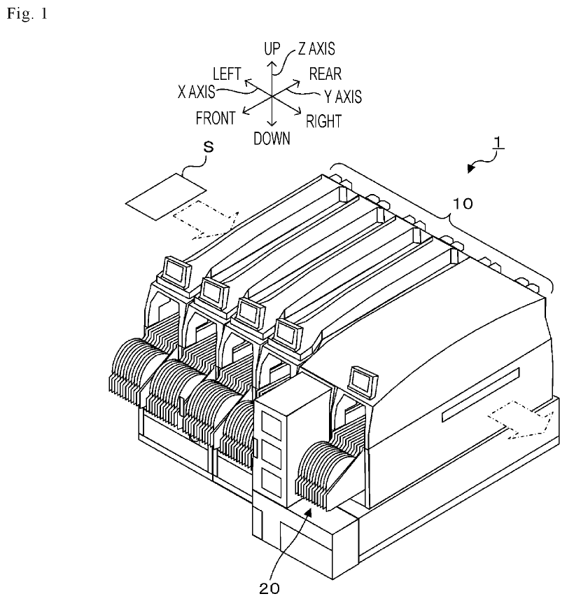

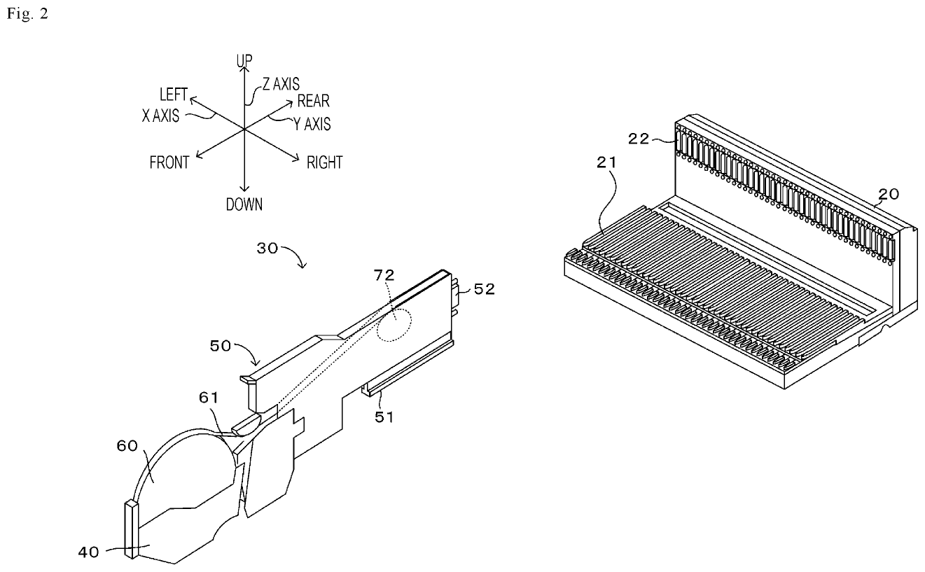

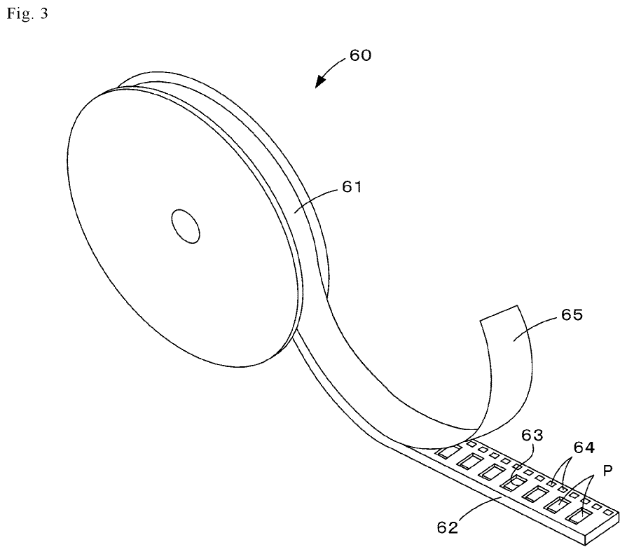

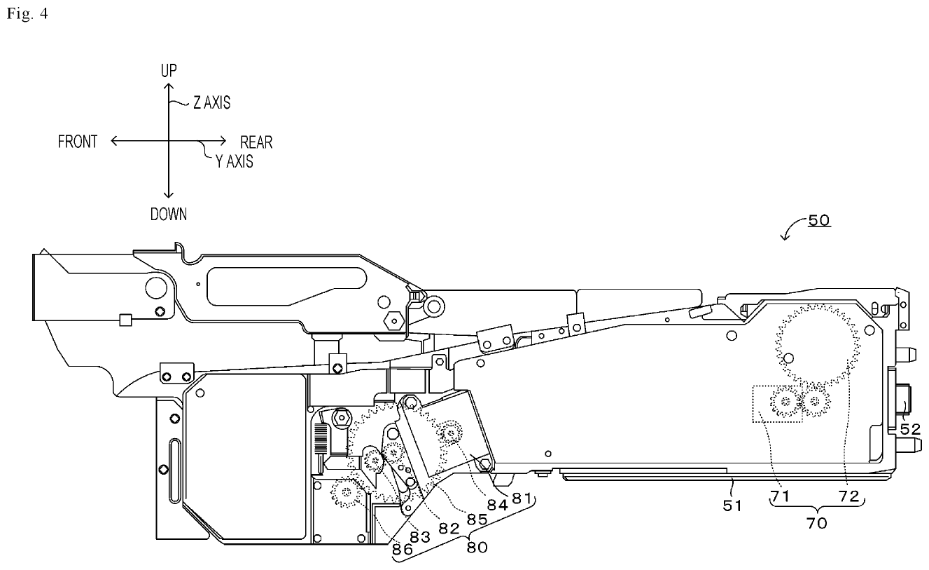

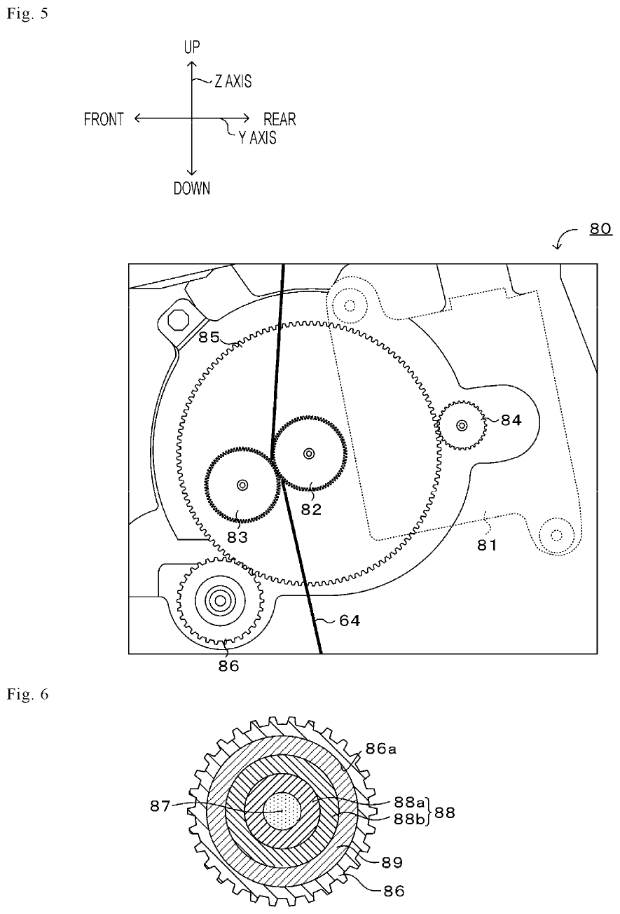

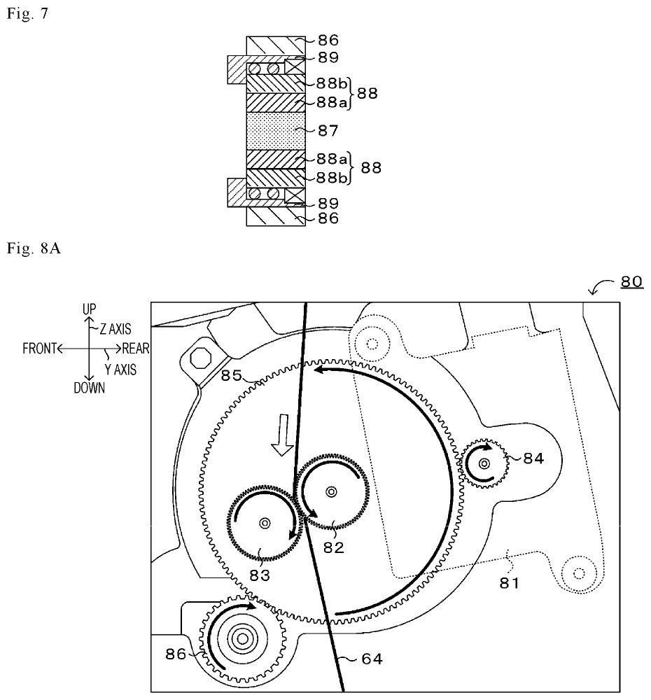

With reference to drawings, a preferred embodiment of the present disclosure will be described below. FIG. 1 is a schematic configuration view of component mounting system 1. FIG. 2 is a perspective view of feeder table 20 and tape feeder 30. FIG. 3 is a perspective view of tape reel 60. FIG. 4 is a side view of main body portion 50. FIG. 5 is a side view of cover tape pull-in mechanism 80. FIG. 6 is a cross-sectional view of rotation gear 86 taken along a plane orthogonal to fixed shaft 87. FIG. 7 is a cross-sectional view of rotation gear 86 taken along a plane passing through fixed shaft 87. A left-right direction illustrated in FIGS. 1 and 2 is an X-axis direction (a direction perpendicular to a paper surface in FIGS. 4, 5, 8A, and 8B), a front-rear direction illustrated in FIGS. 1, 2, 4, and 5 is a Y-axis direction, and an up-down direction illustrated in FIGS. 1, 2, 4, and 5 is a Z-axis direction. For convenience of description, carrier tape feeding mechanism 70, pair of pull-in gears 82 and 83, motor gear 84, drive gear 85, and rotation gear 86 are indicated by broken lines in FIG. 4, and drive motor 81 is indicated by broken lines in FIG. 5.

Component mounting system 1 is configured to produce board S on which component P is mounted, and includes multiple component mounters 10 arranged along a conveyance direction of board S. In addition, component mounting system 1 includes a printing machine that prints solder on board S, a print inspection machine that inspects a state of the solder printed by the printing machine, a visual inspection device that inspects whether component P is mounted at a correct position of board S, a reflow device that fixes component P to board S by heating board S to melt the solder and cooling board S to electrically connect component P to board S, a management device that manages entire component mounting system 1, and the like.

Component mounter 10 collects component P supplied from tape feeder 30 by a collecting member and mounts component P on board S. Component mounter 10 includes a head capable of holding multiple collecting members, a head moving device for horizontally moving the head, a lifting and lowering device for vertically moving the collecting members with respect to the head, a control device for controlling entire component mounter 10, and the like.

As illustrated in FIG. 2, tape feeder 30 is set on feeder table 20 provided in component mounter 10. As illustrated in FIG. 2, tape feeder 30 includes holding section 40, main body portion 50, rail 51 provided at a lower portion of main body portion 50, and connector 52 provided at a tip portion of main body portion 50. In addition, tape feeder 30 includes a control device that controls entire tape feeder 30, and the like. Feeder table 20 has multiple slots 21 for holding tape feeder 30 in a removable manner. Rail 51 provided at a lower portion of main body portion 50 of tape feeder 30 is inserted into each slot 21. Connector 22 corresponding to each of slots 21 is provided on an upright wall provided at a rear end of feeder table 20. Connector 52 of tape feeder 30 is electrically connected to connector 22 of feeder table 20.

Holding section 40 holds tape reel 60. As illustrated in FIG. 3, tape reel 60 is formed by winding a component supply tape 61. Component supply tape 61 is obtained by attaching cover tape 65 to carrier tape 62 in which component P is accommodated in each of multiple recessed portions 63. In carrier tape 62, sprocket holes 64 are formed at equal intervals.

As illustrated in FIG. 4, main body portion 50 includes carrier tape feeding mechanism 70 and cover tape pull-in mechanism 80. Carrier tape feeding mechanism 70 pulls out carrier tape 62 (component supply tape 61) from tape reel 60, and feeds carrier tape 62 to a component supply position. Carrier tape feeding mechanism 70 includes sprocket 72 provided with an engagement claw that engages with sprocket hole 64 on an outer periphery thereof, and drive motor 71 that rotationally drives sprocket 72. Drive motor 71 is, for example, a stepping motor.

Tape feeder 30 subsequently supplies the components P accommodated in carrier tape 62 to the component supply positions by causing drive motor 71 to drive sprocket 72 by a predetermined rotation amount and feeding carrier tape 62 engaged with sprocket 72 by a predetermined amount. Component P accommodated in carrier tape 62 is brought into an exposed state at the component supply position by peeling off cover tape 65 in front of the component supply position, and is collected by the collecting member. Cover tape 65 attached to carrier tape 62 is folded back in a direction opposite to a feeding direction of carrier tape 62 in front of the component supply position, and is peeled off from carrier tape 62 by being fed in the opposite direction by cover tape pull-in mechanism 80.

As illustrated in FIGS. 4 and 5, cover tape pull-in mechanism 80 includes drive motor 81, pair of pull-in gears 82 and 83, motor gear 84, drive gear 85, and rotation gear 86. Drive motor 81 is, for example, a stepping motor.

Pair of pull-in gears 82 and 83 meshes with each other. In pair of pull-in gears 82 and 83, first pull-in gear 82 of pair of pull-in gears 82 and 83 is a drive gear that rotates by torque transmitted from drive motor 81. Second pull-in gear 83 is a driven gear that is rotated in a direction opposite to pull-in gear 82 in accordance with the rotation of first pull-in gear 82. For example, in FIG. 5, second pull-in gear 83 is provided in front of first pull-in gear 82.

Motor gear 84 is attached to a rotation shaft of drive motor 81. Motor gear 84 is provided on a side (for example, a rear side of first pull-in gear 82 in FIG. 5) opposite to second pull-in gear 83 with respect to first pull-in gear 82.

Drive gear 85 is coaxially connected to pull-in gear 82 to rotate integrally with pull-in gear 82. Drive gear 85 meshes with motor gear 84 and rotation gear 86. Drive gear 85 has an outer diameter larger than the diameter of first pull-in gear 82 and including second pull-in gear 83 in an axial view when drive gear 85 is viewed in the axial direction. Drive gear 85 is rotated in a direction opposite to motor gear 84 in accordance with the rotation of motor gear 84.

In FIG. 5, when motor gear 84 is rotated clockwise by the torque from drive motor 81, drive gear 85 meshing with motor gear 84 and pull-in gear 82 coaxially connected to drive gear 85 are rotated counterclockwise, and pull-in gear 83 meshing with pull-in gear 82 is rotated clockwise. Pair of pull-in gears 82 and 83 pulls in cover tape 65 and peel off cover tape 65 from carrier tape 62 by rotating in this manner in a state where cover tape 65 is sandwiched. Meanwhile, in FIG. 5, when motor gear 84 is rotated counterclockwise by the torque from drive motor 81, drive gear 85 and pull-in gear 82 coaxially connected to drive gear 85 are rotated clockwise, and pull-in gear 83 meshed with pull-in gear 82 is rotated counterclockwise. Pair of pull-in gears 82 and 83 rotate in this manner in a state in which cover tape 65 is sandwiched therebetween, thereby conveying (hereinafter, referred to as return) cover tape 65 in a direction opposite to the direction in which cover tape 65 is pulled in.

Rotation gear 86 is disposed at a position different from motor gear 84 with respect to first pull-in gear 82. Specifically, rotation gear 86 is provided on the side (for example, obliquely below the front of drive gear 85 in FIG. 5) opposite to drive motor 81 in a state where first pull-in gear 82 is sandwiched therebetween. Rotation gear 86 is meshed with first pull-in gear 82 via drive gear 85. Rotation gear 86 is provided with one-way clutch 88 and torque limiter 89.

As illustrated in FIGS. 6 and 7, one-way clutch 88 includes inner ring member 88a and outer ring member 88b. Inner ring member 88a is non-rotatably fixed to fixed shaft 87 fixed to the case of main body portion 50. Outer ring member 88b is provided to be capable of idling in one direction (clockwise in FIG. 5) with respect to inner ring member 88a. One-way clutch 88 is attached such that outer ring member 88b idles (for example, idles clockwise in FIG. 5) with respect to inner ring member 88a in accordance with the rotation (for example, counterclockwise rotation in FIG. 5) of first pull-in gear 82 (drive gear 85) when cover tape 65 is pulled in. One-way clutch 88 is, for example, a roller one-way clutch.

As illustrated in FIGS. 6 and 7, torque limiter 89 is provided coaxially with one-way clutch 88. Torque limiter 89 is disposed to be interposed between the inner peripheral surface of annular rotation gear 86 and the outer peripheral surface of outer ring member 88b of one-way clutch 88. When a torque exceeding a specified torque acts on rotation gear 86, torque limiter 89 performs slip rotation with respect to outer ring member 88b of one-way clutch 88. Torque limiter 89 is, for example, a spring torque limiter.

Rotation gear 86 is a gear that allows or limits rotation of drive gear 85 (pull-in gear 82). That is, in FIG. 5, when a clockwise torque acts on rotation gear 86, outer ring member 88b idles clockwise relative to inner ring member 88a regardless of the magnitude of the torque value. Therefore, idling of one-way clutch 88 causes drive gear 85 and first pull-in gear 82 provided coaxially with drive gear 85 to rotate counterclockwise. Accordingly, the pull-in operation of cover tape 65 is performed by pair of pull-in gears 82 and 83. In this way, when the clockwise torque acts on rotation gear 86, cover tape 65 can be pulled in regardless of the magnitude of the torque value. In FIG. 5, when a counterclockwise torque acts on rotation gear 86, one-way clutch 88 is locked to limit the clockwise rotation of drive gear 85 by the clockwise torque of drive gear 85. In this case, when a torque exceeding the specified torque of torque limiter 89 acts on rotation gear 86, torque limiter 89 slips counterclockwise with respect to one-way clutch 88, and rotation gear 86 rotates counterclockwise. Therefore, clockwise rotation of drive gear 85 and first pull-in gear 82 provided coaxially with drive gear 85 is allowed. Accordingly, the return operation of cover tape 65 is performed by pair of pull-in gears 82 and 83.

In tape feeder 30, one-way clutch 88 and torque limiter 89 are provided in rotation gear 86 different from pair of pull-in gears 82 and 83. Therefore, compared to a case where one-way clutch 88 and torque limiter 89 are provided in pull-in gears 82 and 83, pull-in gears 82 and 83 are downsized. Accordingly, an empty space can be secured around pair of pull-in gears 82 and 83. In tape feeder 30, drive motor 81 and motor gear 84 can be disposed in the space. Further, tape feeder 30 includes drive gear 85 that is provided coaxially with pull-in gear 82, rotates integrally with first pull-in gear 82, and meshes with motor gear 84 and rotation gear 86. Even when rotation gear 86 is provided on the same side as motor gear 84 with first pull-in gear 82 sandwiched therebetween to directly mesh with first pull-in gear 82, a space is occupied by drive motor 81, motor gear 84, and the like, and thus rotation gear 86 cannot be disposed. Even when rotation gear 86 is provided on the side opposite to motor gear 84 with first pull-in gear 82 sandwiched therebetween to directly mesh with first pull-in gear 82, rotation gear 86 may interfere with second pull-in gear 83. Meanwhile, in many cases, there is a space in which rotation gear 86 can be disposed without interfering with another member (for example, second pull-in gear 83) on the side opposite to motor gear 84 with first pull-in gear 82 sandwiched therebetween in drive gear 85. Therefore, it is significant to provide drive gear 85 in tape feeder 30. Drive gear 85 has an outer diameter larger than the outer diameter of pull-in gear 82 and includes second pull-in gear 83 in an axial view when viewed in the axial direction. Therefore, rotation gear 86 and second pull-in gear 83 do not interfere with each other. Accordingly, in tape feeder 30, it is particularly significant to adopt such a configuration.

Next, the operation of tape feeder 30 configured as described above will be described. First, the operation of tape feeder 30 when tape feeder 30 is mounted on feeder table 20 by the operator will be described.

First, the operator sets tape feeder 30 in slot 21 in which tape feeder 30 is not set among slots 21 provided in feeder table 20. Subsequently, the operator pulls out component supply tape 61 from tape reel 60 to the component supply position, and fits sprocket 72 of carrier tape feeding mechanism 70 into sprocket hole 64 provided in carrier tape 62. Then, when the operator peels off cover tape 65 from carrier tape 62 and folds back cover tape 65 in the direction opposite to the feeding direction of carrier tape 62 in front of the component supply position, the operator sandwiches the end portion of cover tape 65 between pair of pull-in gears 82 and 83. Then, the operator outputs a pull-in instruction to the control device of tape feeder 30.

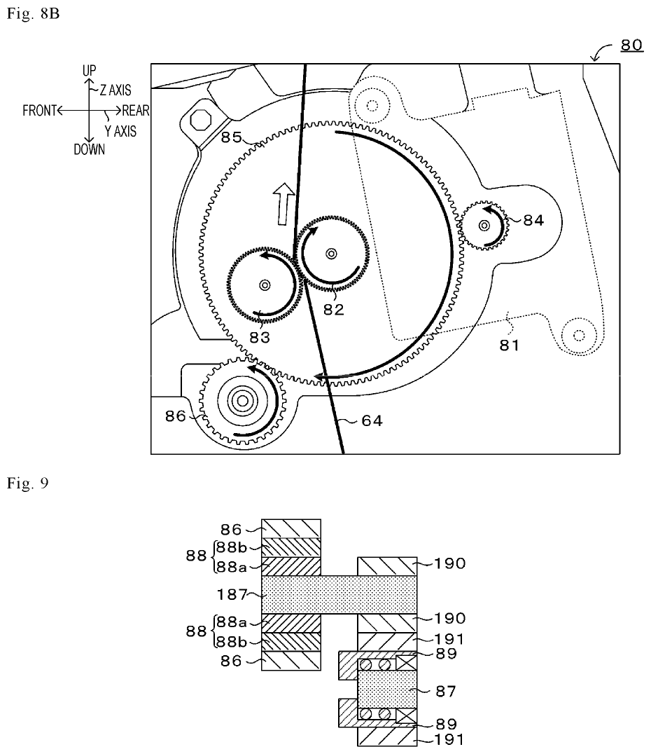

After the pull-in instruction is input, the control device of tape feeder 30 drives and controls drive motor 81 such that drive gear 85 and pull-in gear 82 rotate counterclockwise as illustrated in FIG. 8A. In this case, idling of one-way clutch 88 provided in rotation gear 86 causes drive gear 85 to rotate counterclockwise. Accordingly, pull-in gear 82 rotates counterclockwise together with drive gear 85, and the pull-in gear 83 rotates clockwise as pull-in gear 82 rotates counterclockwise. Accordingly, pair of pull-in gears 82 and 83 are rotated by a relatively small torque of drive motor 81, and cover tape 65 is pulled in by the rotation of pair of pull-in gears 82 and 83.

After confirming that cover tape 65 is stretched by the above-described process, the operator outputs a pull-in stop instruction to the control device of tape feeder 30.

When the above-described operation is performed, the operator may erroneously peel off and pull out cover tape 65 excessively, or cover tape 65 may be excessively stretched. In such a case, the operator outputs a return instruction to the control device of tape feeder 30.

When the return instruction is input, as illustrated in FIG. 8B, the control device of tape feeder 30 drives and controls drive motor 81 such that drive gear 85 rotates clockwise when torque exceeding the specified torque of torque limiter 89 acts on rotation gear 86 via motor gear 84 and drive gear 85. At this time, drive gear 85 is rotated clockwise with a slip of torque limiter 89 provided in rotation gear 86. Accordingly, pull-in gear 82 rotates clockwise together with drive gear 85, and the pull-in gear 83 rotates counterclockwise as pull-in gear 82 rotates clockwise. Accordingly, pair of pull-in gears 82 and 83 are rotated by a torque exceeding the specified torque of drive motor 81, and cover tape 65 is returned by pair of pull-in gears 82 and 83. In this case, drive motor 81 needs to output a relatively large torque, but the frequency of execution of the return operation is low, the execution time is short, and thus, problems such as heat generation do not occur.

After returning cover tape 65 by a desired amount, the operator outputs a return stop instruction to the control device of tape feeder 30. The control device of tape feeder 30 stops drive motor 81 after the return stop instruction is input.

Next, a component supply process of tape feeder 30 when component P is supplied to component mounter 10 will be described. This process is executed after a supply request of component P is input from the control device of component mounter 10 on which tape feeder 30 is mounted. When this routine is started, the control device of tape feeder 30 drives and controls drive motor 71 of carrier tape feeding mechanism 70 such that sprocket 72 rotates by a predetermined rotation amount and carrier tape 62 is fed by a predetermined amount, and also drives and controls drive motor 81 of cover tape pull-in mechanism 80 such that cover tape 65 is pulled in by an amount equivalent to fed carrier tape 62. Thus, the tension applied to cover tape 65 is kept constant.

When drive motor 71 and drive motor 81 are stopped for some reason during execution of such process, cover tape 65 is held without being loosened as follows. That is, in rotation gear 86, counterclockwise torque acts on rotation gear 86 based on the tension of cover tape 65. Thus, one-way clutch 88 is locked. The torque acting on rotation gear 86 does not exceed the specified torque of torque limiter 89. Therefore, when one-way clutch 88 is locked, torque limiter 89 does not slip and rotate with respect to outer ring member 88b of one-way clutch 88. Therefore, the rotation of drive gear 85 and pull-in gear 82 coaxially connected to drive gear 85 is limited by rotation gear 86, and the stop state is maintained. Thus, cover tape 65 is held without being loosened.

Here, a correspondence relationship between elements of the present embodiment and elements disclosed in claims will be described. That is, tape feeder 30 of the present embodiment corresponds to a tape feeder of the present disclosure, pair of pull-in gears 82 and 83 correspond to a pair of feed gears, drive motor 81 corresponds to a drive motor, rotation gear 86 corresponds to a rotation gear, one-way clutch 88 corresponds to a one-way clutch, and torque limiter 89 corresponds to a torque limiter. Motor gear 84 corresponds to a motor gear, and drive gear 85 corresponds to a drive gear.

In tape feeder 30 described in detail above, one-way clutch 88 and torque limiter 89 are not provided in pull-in gears 82 and 83. Therefore, compared to a case where one-way clutch 88 and torque limiter 89 are provided in pull-in gears 82 and 83, pull-in gears 82 and 83 are downsized. Accordingly, a space in which other members such as drive motor 81 can be disposed becomes large in the vicinity of pull-in gears 82 and 83, and other members such as drive motor 81 can be easily disposed in the vicinity of pair of pull-in gears 82 and 83. Accordingly, it is possible to effectively utilize a limited space and to suppress an increase in size of entire tape feeder 30 even when one-way clutch 88 and torque limiter 89 are disposed.

In tape feeder 30, drive motor 81 is disposed at a position different from rotation gear 86 such that motor gear 84 attached to drive motor 81 indirectly meshes with first pull-in gear 82. Further, in tape feeder 30, motor gear 84 is disposed on the side opposite to rotation gear 86 with pair of pull-in gears 82 and 83 sandwiched therebetween. Therefore, it is possible to prevent drive motor 81 or motor gear 84 and rotation gear 86 from interfering with each other while suppressing an increase in size of entire tape feeder 30. Further, tape feeder 30 includes drive gear 85 that meshes with motor gear 84 and rotation gear 86 and rotates integrally with first pull-in gear 82. Even when rotation gear 86 is provided on the same side as motor gear 84 with first pull-in gear 82 sandwiched therebetween to directly mesh with first pull-in gear 82, a space is occupied by drive motor 81, motor gear 84, and the like, and thus rotation gear 86 cannot be disposed. Even when rotation gear 86 is provided on the side opposite to motor gear 84 with first pull-in gear 82 sandwiched therebetween to directly mesh with first pull-in gear 82, rotation gear 86 may interfere with second pull-in gear 83. Meanwhile, in many cases, there is a space in which rotation gear 86 can be disposed without interfering with another member (for example, second pull-in gear 83) on the side opposite to motor gear 84 with first pull-in gear 82 sandwiched therebetween in drive gear 85. Therefore, it is significant to provide drive gear 85 in tape feeder 30. Drive gear 85 has an outer diameter larger than the outer diameter of first pull-in gear 82 of pair of pull-in gears 82 and 83 and including second pull-in gear 83 in an axial view when viewed in the axial direction. Therefore, rotation gear 86 and second pull-in gear 83 do not interfere with each other. Accordingly, in tape feeder 30, it is particularly significant to adopt such a configuration.

In tape feeder 30, one-way clutch 88 and torque limiter 89 are provided coaxially. Therefore, compared to a case where one-way clutch 88 and torque limiter 89 are provided on different shafts, the tape feeder itself can be downsized.

The present disclosure is not limited to the embodiment that has been described heretofore at all, and needless to say, the present disclosure may be carried out in various aspects without departing from the technical scope thereof.

For example, in the above-described embodiment, rotation gear 86 is meshed with first pull-in gear 82 via drive gear 85. However, rotation gear 86 may directly mesh with pull-in gear 82 or may directly mesh with second pull-in gear 83.

In the above-described embodiment, one-way clutch 88 and torque limiter 89 are coaxially provided in rotation gear 86. However, as illustrated in FIG. 9, one-way clutch 88 and torque limiter 89 may be provided on different shafts. That is, one-way clutch 88 is provided to be interposed between the inner peripheral surface of rotation gear 86 and rotation shaft 187 that is rotatably attached to the case of main body portion 50. Torque limiter 89 is provided in gear 191 that meshes with rotation gear 86 via gear 190. Gear 190 is provided coaxially with rotation gear 86. Torque limiter 89 is interposed between the inner peripheral surface of gear 191 and fixed shaft 87 fixed to the case of main body portion 50. In FIG. 9, the same elements as those in FIGS. 6 and 7 are denoted by the same reference numerals, and description thereof is omitted. However, in consideration of downsizing entire tape feeder 30, one-way clutch 88 and torque limiter 89 are preferably provided coaxially.

The above-described embodiment has been described as the tape feeder, the description may be interpreted as a method for feeding a cover tape.

### INDUSTRIAL APPLICABILITY

The present disclosure can be used for a manufacturing industry of a tape feeder or a component mounter.

### REFERENCE SIGNS LIST

1: component mounting system, 10: component mounter, 20: feeder table, 21: slot, 22: connector, 30: tape feeder, 40: holding section, 50: main body portion, 51: rail, 52: connector, 60: tape reel, 61: component supply tape, 62: carrier tape, 63: recessed portion, 64: sprocket hole, 65: cover tape, 70: carrier tape feeding mechanism, 71: drive motor, 72: sprocket, 80: cover tape pull-in mechanism, 81: drive motor, 82: pull-in gear, 83: pull-in gear, 84: motor gear, 85: drive gear, 86: rotation gear, 87: fixed shaft, 88: one-way clutch, 88a: inner ring member, 88b: outer ring member, 89: torque limiter, 190, 191: gear, P: component, S: board

1. A tape feeder for feeding a component supply tape, in which a cover tape is attached to a carrier tape accommodating multiple components, to a predetermined supply position and peeling off the cover tape from the carrier tape in front of the supply position to expose the component on the carrier tape, the tape feeder comprising:
a pair of feed gears configured to mesh with each other and sandwich the cover tape;
a drive motor configured to rotationally drive the pair of feed gears such that the carrier tape is pulled in;
a rotation gear directly or indirectly meshed with a first feed gear of the pair of feed gears;
a one-way clutch provided in the rotation gear such that the rotation gear idles with respect to rotation of the pair of feed gears in a direction in which the carrier tape is pulled in; and
a torque limiter provided in the rotation gear or another rotation gear meshing with the rotation gear.

2. The tape feeder according to claim 1,
wherein the drive motor is disposed such that a motor gear attached to the drive motor directly or indirectly meshes with the first feed gear at a position different from the rotation gear.

3. The tape feeder according to claim 2,
wherein the drive motor is disposed on a side opposite to the rotation gear with the first feed gear sandwiched therebetween.

4. The tape feeder according to claim 3, further comprising:
a drive gear configured to mesh with the motor gear and the rotation gear and rotate integrally with the first feed gear.

5. The tape feeder according to claim 4,
wherein the drive gear has an outer diameter larger than an outer diameter of the first feed gear of the pair of feed gears, the outer diameter including a second feed gear of the pair of feed gears in an axial view when viewed in an axial direction.

6. The tape feeder according to claim 1,
wherein the one-way clutch and the torque limiter are provided coaxially.

7. A method for feeding a cover tape by using a pair of feed gears capable of rotating in opposite directions to each other in a state in which a carrier tape accommodating multiple components is sandwiched in a component supply tape in which the cover tape is attached to the carrier tape, the method comprising:
causing a rotation gear to directly or indirectly mesh with a first feed gear of the pair of feed gears;
causing the rotation gear to idle with respect to rotation of the first feed gear in a direction in which the cover tape is pulled in to peel off the cover tape; and
causing the rotation gear to slip with respect to rotation of the first feed gear in a direction in which the cover tape is fed to a side opposite to a peeling direction of the cover tape.
